(19) United States
(12) Patent Application Publication
(10) Pub. No.: US 2013/0244178 A1
(43) Pub. Date: Sep. 19, 2013

(54) PHOTORESISTS COMPRISING MULTI-AMIDE COMPONENT

(71) Applicants: Gregory P. Prokopowicz, Worcester, MA (US); Gerhard Pohlers, Needham, MA (US); Cong Liu, Shrewsbury, MA (US); Chunyi Wu, Shrewsbury, MA (US); Cheng-Bai Xu, Southborough, MA (US); Joon Seok Oh, Natick, MA (US)

(72) Inventors: Gregory P. Prokopowicz, Worcester, MA (US); Gerhard Pohlers, Needham, MA (US); Cong Liu, Shrewsbury, MA (US); Chunyi Wu, Shrewsbury, MA (US); Cheng-Bai Xu, Southborough, MA (US); Joon Seok Oh, Natick, MA (US)

(73) Assignee: Rohm and Haas Electronic Materials LLC, Marlborough, MA (US)

(21) Appl. No.: 13/607,728

(22) Filed: Sep. 9, 2012

Related U.S. Application Data
(60) Provisional application No. 61/533,128, filed on Sep. 9, 2011.

(51) Int. Cl. G03F 7/004; G03F 7/20

(52) U.S. Cl. CPC G03F 7/004; G03F 7/20
USPC 430/281.1; 430/325

(57) ABSTRACT

New photoresist compositions are provided that comprise a component that comprises two or more amide groups. Preferred photoresists of the invention may comprise a resin with photoacid-labile groups; a photoacid generator compound; and a multi-amide component that can function to decrease undesired photogenrated-acid diffusion out of unexposed regions of a photoresist coating layer

This application claims the benefit of priority under 35 U.S.C. §119(e) to U.S. Provisional Application No. 61/533,128, filed Sep. 9, 2011, the entire contents of which application are incorporated herein by reference.

This invention relates to photoresist compositions that comprise a component that comprises two or more amide groups. Preferred photoresists of the invention may comprise a resin with photoacid-labile groups; a photoacid generator compound; and a multi-amide component that can function to decrease undesired photogenerated-acid diffusion out of unexposed regions of a photoresist coating layer.

Photoresists are photosensitive films for transfer of images to a substrate. They form negative or positive images. After coating a photoresist on a substrate, the coating is exposed through a patterned photomask to a source of activating energy, such as ultraviolet light, to form a latent image in the photoresist coating. The photomask has areas opaque and transparent to activating radiation that define an image desired to be transferred to the underlying substrate.

Known photoresists can provide features having resolution and size sufficient for many existing commercial applications. However for many other applications, the need exists for new photoresists that can provide highly resolved images of sub-quarter-micron (<0.25 μm) dimension.

Various attempts have been made to alter the make-up of photoresist compositions to improve performance of functional properties. Among other things, a variety of basic compounds have been reported for use in photoresist compositions. See, e.g., U.S. Pat. Nos. 6,607,870 and 7,379,548, as well as Japanese published patent application JP 61219951.

The present invention provides photoresist compositions comprising a resin, a photoacid generator compound (photoacid generator or “PAG”), and a acid diffusion control agent that comprises a multi-amide component of the formula:

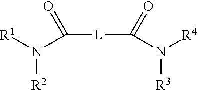

wherein R¹, R², R³, and R⁴ are independently chosen from H, (C₁-C₃₀)alkyl, and amido-substituted (C₁-C₃₀)alkyl; R¹ and R², or R¹ and R³ or R³ and R⁴ may be taken together along with the atoms to which they are attached to form a 5- to 12-membered heterocyclic ring; and L is a linking group providing a spacing of 3 to 8 atoms between the carbonyl groups; wherein the multi-amide compound is free of hydroxyl groups. Such multi-amide component comprises more than one amide group. Such photoresists may be either positive-acting or negative-acting, and preferably are positive-acting.

In a preferred aspect, photoresists of the invention used for short-wavelength imaging applications, such as 193 nm imaging.

Particularly preferred photoresists of the invention may be used in immersion lithography applications.

As used herein, the term “alkyl” includes linear, branched and cyclic alkyl. The term “(meth)acrylate” includes both acrylate and methacrylate. Likewise, the term “(meth)acrylic” includes acrylic and methacrylic. The articles “a” and “an” refer to the singular and the plural. The following abbreviations shall have the following meanings: ° C.=degrees Celsius; nm=nanometers; μm=micron=micrometer; cm=centimeter; mJ=milliJoules; wt %=weight percent; and PAG=photoacid generator.

We have found that use of certain multi-amide compounds in a photoresist composition, including chemically-amplified photoresist compositions, can significantly enhance resolution of a relief image (for example, fine lines) of the resist. In particular, we have found that a multi-amide compound having a spacing of 3 to 8 atoms between the amide carbonyl groups imparts significantly enhanced lithographic results, including relative to a comparable photoresist that is otherwise identical to the photoresist that instead contains an additive with a single amide group or a different arrangement of multi-amide groups, or that contains other types of basic additives such as a multiple amine-containing compound. Use of the multi-amide compounds of the invention also can provide good shelf life to photoresists containing the compounds. Without being bound by any theory, it is believed that a multi-amide compound additive can more effectively complex with photogenerated acid in an exposed region of a photoresist layer and thereby prevent undesired migration of the acid into unexposed resist layer regions, relative to the complexing provided by a comparable additive that contains a single amide moiety. That is, the present multi-amide compounds suitably function as quenchers for photogenerated acid during lithography.

The multi-amide compounds of the invention comprise two or more amide moieties. Preferably, the present multi-amide compounds have from 2 to 6 amide groups, more preferably from 2 to 4 amide groups, yet more preferably from 2 to 3 amide groups and most preferably 2 amide groups. These multi-amide compounds function to complex photogenerated acid under the conditions of lithography and are sufficiently soluble or dispersible in the photoresist formulation used.

Multi-amide compounds suitable for use in the present invention have the formula:

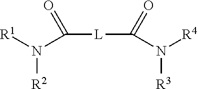

wherein R¹, R², R³, and R⁴ are independently chosen from H, (C₁-C₃₀)alkyl, and amido-substituted(C₁-C₃₀)alkyl; R¹ and R², or R¹ and R³ or R³ and R⁴ may be taken together along with the atoms to which they are attached to form a 5- to 12-membered heterocyclic ring; and L is a divalent linking group providing a spacing of 3 to 8 atoms between the carbonyl groups; wherein the multi-amide compound is free of hydroxyl groups.

Preferably, R¹, R², R³, and R⁴ are independently chosen from H, (C₁-C₁₀)alkyl, and amido-substituted(C₁-C₁₀)alkyl; more preferably R¹, R², R³, and R⁴ are independently chosen from H, (C₁-C₈)alkyl, and amido-substituted(C₁-C₈)alkyl; and still more preferably R¹, R², R³, and R⁴ are independently chosen from H, (C₁-C₆)alkyl, and amido-substituted(C₁-C₆)alkyl. L may be any suitable linking group that provides from 3 to 8 atoms between the amide carbonyls. Preferably, L is chosen from (C₃-C₁₂)alkylene, ((C₁-C₆)alkylene-O)ₙ(C₁-C₆)alkylene, and 6- to 8-membered heterocyclic rings; wherein n=1-5. More preferably, L is (C₃-C₁₂)alkylene, even more preferably L is (C₃-C₈)alkylene, yet more preferably L is (C₃-C₆)alkylene, and most preferably L is (C₄-C₆)alkylene. Preferably, n=1-4, more preferably n=1-3, and most preferably n=1 or 2.

Optionally, the (C₁-C₃₀)alkyl and amido-substituted(C₁-C₃₀)alkyl groups of R¹-R⁴, and the (C₃-C₁₂)alkylene, ((C₁-C₆)alkylene-O)ₙ(C₁-C₆)alkylene, and 6- to 8-membered heterocyclic rings of L may be substituted with one or more groups chosen from carboxyl (“—CO₂H”), carboxy(C₁-C₃₀)alkyl, (C₁-C₃₀)alkoxy, sulfonyl, sulfonic acid, sulfonate ester, cyano, halo, and keto. Preferred substituent groups are carboxyl, carboxy(C₁-C₁₀)alkyl, (C₁-C₁₀)alkoxy, sulfonyl, sulfonic acid, sulfonate ester, cyano, halo, and keto; and more preferably carboxyl, carboxy(C₁-C₈)alkyl, (C₁-C₈)alkoxy, sulfonyl, sulfonic acid, sulfonate ester, cyano, halo, and keto. Preferred ester groups (carboxyalkyl) are carboxy(C₁-C₆)alkyl. Preferred alkoxy groups are (C₁-C₆)alkoxy, and more preferably (C₁-C₅)alkoxy. By “substituted,” it is meant that one or more hydrogens on an alkyl group or amido-alkyl group of the multi-amide compound is replaced with one or more of the above substituent groups. A mixture of such substituent groups may be used. The presence of such substituent groups may impart desired solubility to the multi-amide compound, or may be used to tailor the quenching ability of the multi-amide compound. Preferably, the (C₁-C₃₀)alkyl and amido-substituted(C₁-C₃₀)alkyl groups of R¹-R⁴, and the (C₃-C₁₂)alkylene, ((C₁-C₆)alkylene-O)ₙ(C₁-C₆)alkylene, and 6- to 8-membered heterocyclic rings of L are not substituted.

When R¹ and R², or R¹ and R³, or R³ and R⁴ are taken together along with the atoms to which they are attached to form a heterocyclic ring, they may form a single heterocyclic ring, or multiple rings which may be used or spirocyclic. It is preferred that when R¹ and R², or R¹ and R³, or R³ and R⁴ are taken together along with the atoms to which they are attached that a 5- to 10-membered ring is formed, and more preferably a 5- to 8-membered ring, and even more preferably a 5 to 6-membered ring. It will be appreciated by those skilled in the art that a lactam is formed when R¹ and R³ are taken together along with the atoms to which they are attached to form a ring. It is preferred that R¹ and R³ are not taken together along with the atoms to which they are attached to form a ring. It is further preferred that R¹ and R² and R³ and R⁴ are not taken together along with the atoms to which they are attached to form a ring.

The amido-substituted(C₁-C₃₀)alkyl groups of formula (I) may contain one or more amide groups. Suitable amide groups may have either of the following formulae (II) or (III):

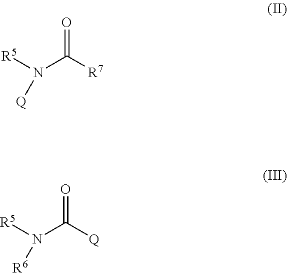

wherein R⁵, R⁶ and R⁷ are independently chosen from H, (C₁-C₃₀)alkyl, and amido-substituted(C₁-C₃₀)alkyl; and wherein Q is a (C₁-C₃₀)alkyl residue. Preferably, R⁵, R⁶ and R⁷ are independently chosen from H, (C₁-C₁₀)alkyl, and amido-substituted(C₁-C₁₀)alkyl, more preferably from H, (C₁-C₈)alkyl, and amido-substituted(C₁-C₈)alkyl, and still more preferably from H and (C₁-C₆)alkyl. It is preferred that the amido-substituted(C₁-C₁₂)alkyl groups of formula (I) contain 1 to 3 amide groups, more preferably from 1 to 2 amido groups, and most preferably 1 amido group. It is preferred that the amido-substituted(C₁-C₁₂)alkyl groups of formula (I) are amido-substituted(C₁-C₆)alkyl groups; and more preferably amido-substituted(C₂-C₆)alkyl groups.

Suitable L groups of formula (I) include, without limitation: propylene; butylene; pentylene; hexylene; cyclohexylene; heptylene; octylene; 2-methylpropylene; 2,2-dimethylpropylene; 2,3-dimethylbutylene; 2,3-diethylbutylene; 2,2-dimethylpentylene; 2,5-dimethylhexylene; 3,4-dimethylhexylene; —CH₂-c-C₆H₁₀—CH₂—; and —C₂H₄-c-C₆H₁₀—C₂H₅—.

Preferred multi-amide compounds for use in photoresists of the invention may have amide groups in a trans-configuration on a cycloalkyl ring, for example, where the amide groups are substituents of a cyclohexyl ring and are arranged in a trans-configuration. Alternatively, preferred multi-amide compounds for use in photoresists of the invention may have amide groups in a cis-configuration on a cycloalkyl ring, for example, where the amide groups are substituents of a cyclohexyl ring and are arranged in a cis-configuration.

Exemplary multi-amide compounds useful in the present invention include, without limitation, one or more of the following: N,N,N′,N′-tetrabutyladipamide; N,N′-dibutyl-N,N′-dimethyldecanediamide; cis-N,N,N′,N′-tetrabutylcyclohexane-1,4-dicarboxamide; and trans-N,N,N′,N′-tetrabutylcyclohexane-1,4-dicarboxamide.

Preferred multi-amide compounds of the invention for use in photoresists may be polymeric or non-polymeric, with non-polymeric multi-amide compounds preferred for many applications. Preferred multi-amide compounds have relatively low molecular weight, for example, a molecular weight of less than or equal to 3000, more preferably ≦2500, ≦2000, ≦1500, ≦1000, ≦800 or even more preferably ≦500.

Multi-amide compounds useful in the present invention are generally commercially available or can be readily synthesized. For instance, an alkylamide compound can be reacted to provide a second amide group.

Preferably, multi-amide compounds of the invention are used in positive-acting or negative-acting chemically amplified photoresists, i.e. negative-acting resist compositions which undergo a photoacid-promoted crosslinking reaction to render exposed regions of a coating layer of the resist less developer soluble than unexposed regions, and positive-acting resist compositions which undergo a photoacid-promoted deprotection reaction of acid labile groups of one or more composition components to render exposed regions of a coating layer of the resist more soluble in an aqueous developer than unexposed regions. Ester groups that contain a tertiary non-cyclic alkyl carbon or a tertiary alicyclic carbon covalently linked to the carboxyl oxygen of the ester are generally preferred photoacid-labile groups of resins employed in photoresists of the invention. Acetal groups also are suitable photoacid-labile groups.

Photoresists of the invention typically comprise a resin binder (polymer), a photoactive component such as a photoacid generator, and a multi-amide compound as described above. Preferably the resin binder has functional groups that impart alkaline aqueous developability to the photoresist composition. For example, preferred are resin binders that comprise polar functional groups such as hydroxyl or carboxylate. Preferably the resin binder is used in a resist composition in an amount sufficient to render the resist developable with an aqueous alkaline solution.

Preferred imaging wavelengths of the photoresists of the invention include sub-300 nm wavelengths, such as 248 nm, and more preferably sub-200 nm wavelengths, such as 193 nm and EUV.

Particularly preferred photoresists of the invention may be used in immersion lithography applications. See, for example, U.S. 2006/0246373 to Rohm and Haas Electronic Materials for a discussion of preferred immersion lithography photoresists and methods. Preferred photoresists for use in immersion application may comprise a resin (which may be fluorinated and/or have photoacid-labile groups) that is separate (not covalently linked) and distinct from a primary resin that has photoacid-labile groups. Thus, the present invention includes in preferred aspects photoresists that comprise: 1) a first resin with photoacid-labile groups; 2) one or more photoacid generator compounds; 3) a second resin that is separate and distinct from the first resin, the second resin may be fluorinated and/or have photoacid-acid groups; and 4) one or more multi-amide compounds.

Particularly preferred photoresists of the invention contain an imaging-effective amount of one or more PAGs and one or more multi-amide compounds as disclosed herein and a resin that is selected from the group of:

1) a phenolic resin that contains acid-labile groups that can provide a chemically amplified positive resist particularly suitable for imaging at 248 nm Particularly preferred resins of this class include: i) polymers that contain polymerized units of a vinyl phenol and an alkyl(meth)acrylate, where the polymerized alkyl (meth)acrylate units can undergo a deblocking reaction in the presence of photoacid. Exemplary alkyl(meth)acrylates that can undergo a photoacid-induced deblocking reaction include e.g. t-butyl acrylate, t-butyl methacrylate, methyladamantyl acrylate, methyl adamantyl methacrylate, and other non-cyclic alkyl and alicyclic(meth)acrylates that can undergo a photoacid-induced reaction, such as polymers in U.S. Pat. Nos. 6,042,997 and 5,492,793, incorporated herein by reference; ii) polymers that contain polymerized units of a vinyl phenol, an optionally substituted vinyl phenyl (e.g. styrene) that does not contain a hydroxy or carboxy ring substituent, and an alkyl(meth)acrylate such as those deblocking groups described with polymers i) above, such as polymers described in U.S. Pat. No. 6,042,997, incorporated herein by reference; and iii) polymers that contain repeat units that comprise an acetal or ketal moiety that will react with photoacid, and optionally aromatic repeat units such as phenyl or phenolic groups;.

2) a resin that is substantially or completely free of phenyl groups that can provide a chemically amplified positive resist particularly suitable for imaging at sub-200 nm wavelengths such as 193 nm Particularly preferred resins of this class include: i) polymers that contain polymerized units of a non-aromatic cyclic olefin (endocyclic double bond) such as an optionally substituted norbornene, such as polymers described in U.S. Pat. No. 5,843,624; ii) polymers that contain alkyl(meth)acrylate units such as e.g. t-butyl acrylate, t-butyl methacrylate, methyladamantyl acrylate, methyl adamantyl methacrylate, and other non-cyclic alkyl and alicyclic(meth)acrylates; such polymers have been described in U.S. Pat. No. 6,057,083. Polymers of this type may contain in preferred aspects certain aromatic groups such as hydroxynaphthyl.

Preferred resins for use in photoresists to be imaged at sub-200 nm, such as at 193 nm, comprises units of the following general formulae (I), (II) and (III):

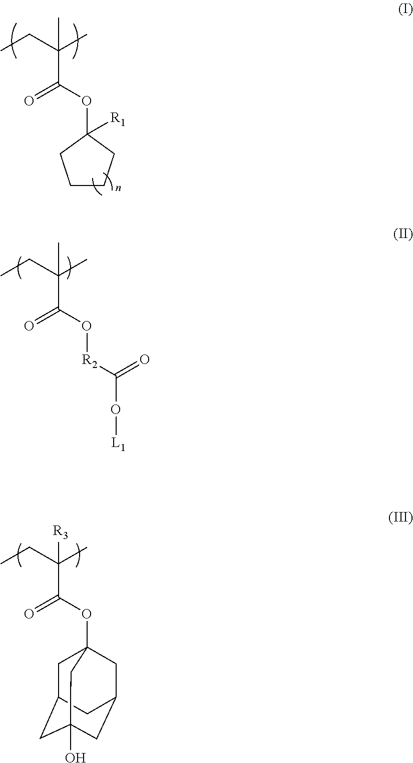

wherein: R₁ is a (C₁-C₃)alkyl group; R₂ is a (C₁-C₃)alkylene group; Li is a lactone group; and n is 1 or 2.

The unit of general formula (I) includes an acid labile group that undergoes a photoacid-promoted deprotection reaction on exposure to activating radiation and heat treatment. This allows for a switch in polarity of the matrix polymer, leading to a change in solubility of the polymer and photoresist composition in an organic developer. Suitable monomers for forming units of formula (I) include, for example, the following:

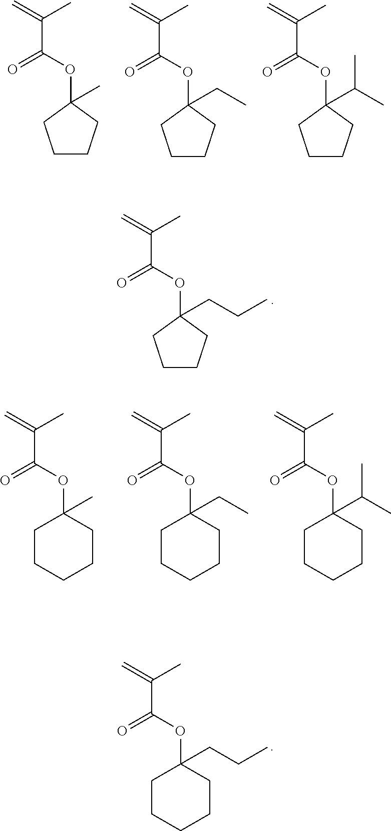

The unit of general formula (II) includes a lactone moiety effective to control the dissolution rate of the matrix polymer and photoresist composition. Suitable monomers for forming units of general formula (II) include, for example, the following:

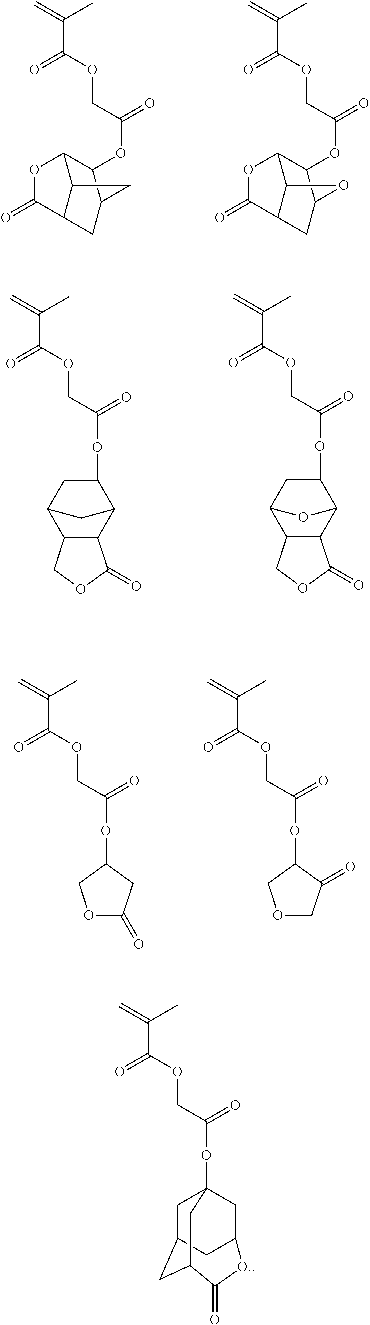

The unit of formula (III) provides a polar group, which enhances etch resistance of the resin and photoresist composition and provides additional means to control the dissolution rate of the resin and photoresist composition. Monomers for forming the unit of formula (III) include 3-hydroxy-l-adamantyl methacrylate (HAMA) and preferably 3-hydroxy-l-adamantyl acrylate (HADA).

The resin can include one or more additional units of general formulae (I), (II) and/or (III) different from the first units. Where additional such units are present in the resin, they will preferably include an additional leaving group-containing unit of formula (I) and/or a lactone-containing unit of formula (II).

In addition to the polymerized units described above, the resin can include one or more additional units which are not of general formula (I), (II) or (III). For example, a particularly suitable lactone group-containing unit is of the following general formula (IV):

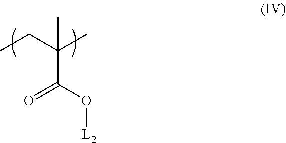

wherein: L₂ is a lactone group; and the unit of general formula (IV) is different from the unit of general formula (II). The following exemplary monomers are suitable for use in forming the additional lactone unit of general formula (IV):

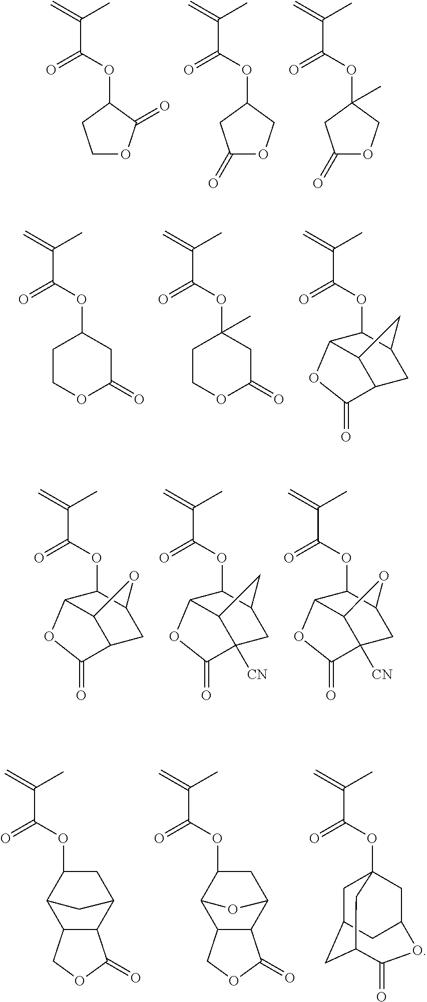

Preferably, L₁ in the unit of general formula (II) and L₂ in the unit of general formula (IV) are independently chosen from the following lactone groups:

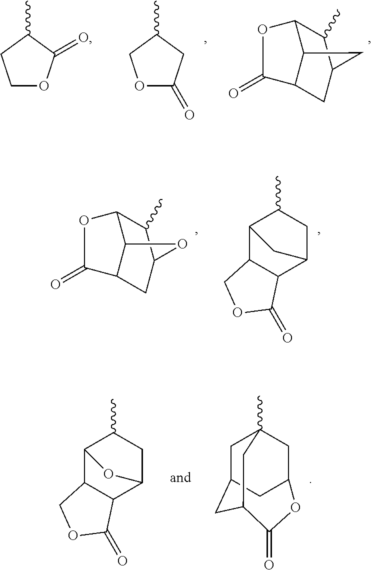

Typically, the additional units for the resin will include the same or similar polymerizable group as those used for the monomers used to form the units of general formula (I), (II) or (III), but may include other, different polymerizable groups in the same polymer backbone, such as those which contain polymerized units of vinyl or a non-aromatic cyclic olefin (endocyclic double bond) such as an optionally substituted norbornene. For imaging at sub-200 nm wavelengths such as 193 nm, the resin is typically substantially free (that is, less than 15 mole %) of phenyl, benzyl or other aromatic groups where such groups are highly absorbing of the radiation. Suitable additional monomeric units for the polymer include, for example, one or more of the following: monomeric units containing ethers, lactones or esters, such as 2-methyl-acrylic acid tetrahydro-furan-3-yl ester, 2-methyl-acrylic acid 2-oxo-tetrahydro-furan-3-yl ester, 2-methyl-acrylic acid 5-oxo-tetrahydro-furan-3-yl ester, 2-methyl-acrylic acid 3-oxo-4,10-dioxa-tricyclo[5.2.1.02,6]dec-8-yl ester, 2-methyl-acrylic acid 3-oxo-4-oxa-tricyclo[5.2.1.02,6]dec-8-yl ester, 2-methyl-acrylic acid 5-oxo-4-oxa-tricyclo [4.2.1.03,7]non-2-yloxycarbonylmethyl ester, acrylic acid 3-oxo-4-oxa-tricyclo[5.2.1.02,6]dec-8-yl ester, 2-methyl-acrylic acid 5-oxo-4-oxa-tricyclo [4.2.1.03,7]non-2-yl ester, and 2-methyl-acrylic acid tetrahydro-furan-3-yl ester; monomeric units having polar groups such as alcohols and fluorinated alcohols, such as 2-methyl-acrylic acid 3-hydroxy-adamantan-1-yl ester, 2-methyl-acrylic acid 2-hydroxy-ethyl ester, 6-vinyl-naphthalen-2-ol, 2-methyl-acrylic acid 3,5-dihydroxy-adamantan-1-yl ester, 2-methyl-acrylic acid 6-(3,3,3-trifluoro-2-hydroxy-2-trifluoromethyl-propyl)-bicyclo[2.2.1]hept-2-yl, and 2-bicyclo[2.2.1]hept-5-en-2-ylmethyl-1,1,1,3,3,3-hexafluoro-propan-2-ol; monomeric units having acid labile moieties, for example, ester groups that contain a tertiary non-cyclic alkyl carbon such as t-butyl, or a tertiary alicyclic carbon such as methyladamantyl or ethylfenchyl covalently linked to a carboxyl oxygen of an ester of the polymer, 2-methyl-acrylic acid 2-(1-ethoxy-ethoxy)-ethyl ester, 2-methyl-acrylic acid 2-ethoxymethoxy-ethyl ester, 2-methyl-acrylic acid 2-methoxymethoxy-ethyl ester, 2-(1-ethoxy-ethoxy)-6-vinyl-naphthalene, 2-ethoxymethoxy-6-vinyl-naphthalene, and 2-methoxymethoxy-6-vinyl-naphthalene. The additional units if used are typically present in the polymer in an amount of from 10 to 30 mol %.

Exemplary preferred resins include, for example, the following:

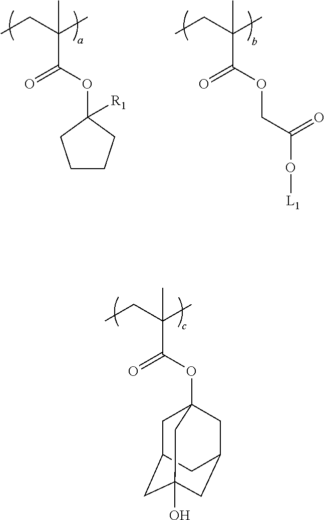

wherein: 0.3<a<0.7; 0.3<b<0.6; and 0.1<c<0.3;

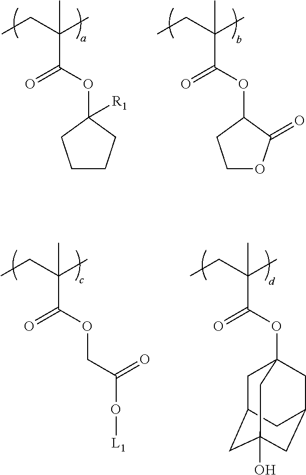

wherein: 0.3<a<0.7; 0.1<b<0.4; 0.1<c<0.4, and 0.1<d<0.3;

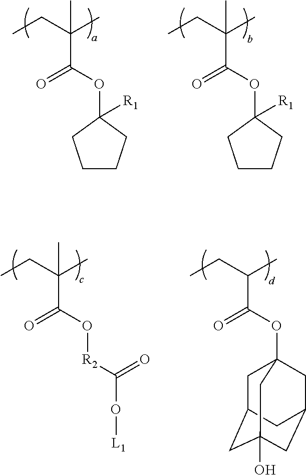

wherein: 0.1<a<0.5; 0.1<b<0.5; 0.2<c<0.6; and 0.1<d<0.3; and

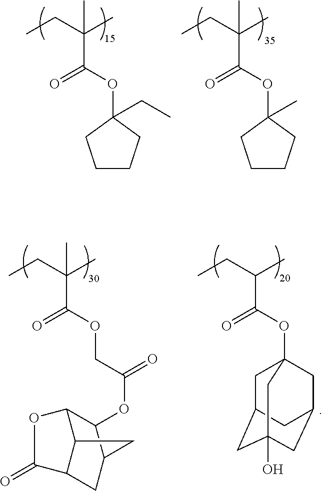

Blends of two or more resins can be used in the compositions of the invention. The resin is present in the resist composition in an amount sufficient to obtain a uniform coating of desired thickness. Typically, the resin is present in the composition in an amount of from 70 to 95 wt % based on total solids of the photoresist composition. Because of improved dissolution properties of the resin in organic developers, useful molecular weights for the resin are not limited to lower values, but cover a very broad range. For example, the weight average molecular weight M_{w} of the polymers is typically less than 100,000, for example, from 5000 to 50,000, more typically from 6000 to 30,000 or from 7,000 to 25,000.

Suitable monomers used in forming the resins are commercially available and/or can be synthesized using known methods. The resins can readily be synthesized by persons skilled in the art using the monomers with known methods and other commercially available starting materials.

Photoresists of the invention also may comprise a single PAG or a mixture of distinct PAGs, typically a mixture of 2 or 3 different PAGs, more typically a mixture that consists of a total of 2 distinct PAGs. The photoresist composition comprises a photoacid generator (PAG) employed in an amount sufficient to generate a latent image in a coating layer of the composition upon exposure to activating radiation. For example, the photoacid generator will suitably be present in an amount of from 1 to 20 wt % based on total solids of the photoresist composition. Typically, lesser amounts of the PAG will be suitable for chemically amplified resists as compared with non-chemically amplified materials.

Suitable PAGs are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Photoresists of the invention comprise one or more multi-amide compounds in a wide amount range, such as from 0.005 to 15 wt %, based on the weight of the PAG, preferably from 0.01 to 15 wt %, and even more preferably from 0.01 to 10 wt %. The added multi-amide component is suitably used in amounts of 0.01, 0.05, 0.1, 0.02, 0.3, 0.4, 0.5 or 1 to 10 or 15 wt % relative to the PAG, and more typically amounts of 0.01, 0.05, 0.1, 0.02, 0.3, 0.4, 0.5 or 1 to 5, 6, 7, 8, 9 or 10 weight percent.

The present photoresist compositions typically comprise a solvent. Suitable solvents include, for example: glycol ethers such as 2-methoxyethyl ether(diglyme), ethylene glycol monomethyl ether, and propylene glycol monomethyl ether; propylene glycol monomethyl ether acetate; lactates such as methyl lactate and ethyl lactate; propionates such as methyl propionate, ethyl propionate, ethyl ethoxy propionate and methyl-2-hydroxy isobutyrate; Cellosolve esters such as methyl Cellosolve acetate; aromatic hydrocarbons such as toluene and xylene; and ketones such as acetone, methylethyl ketone, cyclohexanone and 2-heptanone. A blend of solvents such as a blend of two, three or more of the solvents described above also are suitable. The solvent is typically present in the composition in an amount of from 90 to 99 wt %, more typically from 95 to 98 wt %, based on the total weight of the photoresist composition.

The photoresist compositions can also include other optional materials. For example, the compositions can include one or more of actinic and contrast dyes, anti-striation agents, plasticizers, speed enhancers, sensitizers, and the like. Such optional additives if used are typically present in the composition in minor amounts such as from 0.1 to 10 wt % based on total solids of the photoresist composition.

The photoresists of the invention are generally prepared following known procedures. For example, a photoresist composition of the invention can be prepared by dissolving the components of the photoresist in a suitable solvent. The resin binder component of photoresists resists of the invention are typically used in an amount sufficient to render an exposed coating layer of the resist developable such as with an aqueous alkaline solution. More particularly, a resin binder will suitably comprise 50 to 90 weight percent of total solids of the resist. The photoactive component should be present in an amount sufficient to enable generation of a latent image in a coating layer of the resist. More specifically, the photoactive component will suitably be present in an amount of from 1 to 40 weight percent of total solids of a photoresist. Typically, lesser amounts of the photoactive component will be suitable for chemically amplified resists.

The desired total solids content of the present photoresist compositions will depend on factors such as the particular polymers in the composition, final layer thickness and exposure wavelength. Typically the solids content of the photoresist varies from 1 to 10 wt %, more typically from 2 to 5 wt %, based on the total weight of the photoresist composition.

Preferred negative-acting compositions of the invention comprise a mixture of materials that will cure, crosslink or harden upon exposure to acid, and a photoactive component of the invention. Particularly preferred negative acting compositions comprise a resin binder such as a phenolic resin, a crosslinker component and a photoactive component of the invention. Such compositions and the use thereof has been disclosed in European Patent Applications 0164248 and 0232972 and in U.S. Pat. No. 5,128,232 to Thackeray et al. Preferred phenolic resins for use as the resin binder component include novolaks and poly(vinylphenol)s such as those discussed above. Preferred crosslinkers include amine-based materials, including melamine, glycolurils, benzoguanamine-based materials and urea-based materials. Melamine-formaldehyde resins are generally most preferred. Such crosslinkers are commercially available, e.g. the melamine resins sold by American Cyanamid under the trade names Cymel 300, 301 and 303. Glycoluril resins are sold by American Cyanamid under trade names Cymel 1170, 1171, 1172, urea-based resins are sold under the trade names of Beetle 60, 65 and 80, and benzoguanamine resins are sold under the trade names Cymel 1123 and 1125.

The photoresists of the invention can be used in accordance with known procedures. Though the photoresists of the invention may be applied as a dry film, they are preferably applied on a substrate as a liquid coating composition, dried by heating to remove solvent preferably until the coating layer is tack free, exposed through a photomask to activating radiation, optionally post-exposure baked to create or enhance solubility differences between exposed and nonexposed regions of the resist coating layer, and then developed preferably with an aqueous alkaline developer to form a relief image. The substrate on which a resist of the invention is applied and processed suitably can be any substrate used in processes involving photoresists such as a microelectronic wafer. For example, the substrate can be a silicon, silicon dioxide or aluminum-aluminum oxide microelectronic wafer. Gallium arsenide, ceramic, quartz or copper substrates may also be employed. Substrates used for liquid crystal display and other flat panel display applications are also suitably employed, for example, glass substrates, indium tin oxide coated substrates and the like. A liquid coating resist composition may be applied by any standard means such as spinning, dipping or roller coating.

The exposure energy should be sufficient to effectively activate the photoactive component of the radiation sensitive system to produce a patterned image in the resist coating layer. Suitable exposure energies typically range from 1 to 300 mJ/cm². As discussed above, preferred exposure wavelengths include sub-200 nm such as 193 nm

The photoresist layer (with overcoated barrier composition layer, if present) may be preferably exposed in an immersion lithography system, i.e. where the space between the exposure tool (particularly the projection lens) and the photoresist coated substrate is occupied by an immersion fluid, such as water or water mixed with one or more additives such as cesium sulfate which can provide a fluid of enhanced refractive index. Preferably the immersion fluid (for example, water) has been treated to avoid bubbles, for example water can be degassed to avoid nanobubbles.

References herein to “immersion exposing” or other similar term indicates that exposure is conducted with such a fluid layer (for example, water or water with additives) interposed between an exposure tool and the coated photoresist composition layer.

After exposure, a thermal treatment is typically employed for chemically-amplified photoresists. Suitable post-exposure bake temperatures are from about 50° C. or greater, more specifically from 50 to 140° C. For an acid-hardening negative-acting resist, a post-development bake may be employed if desired at temperatures of from 100 to 150° C. for several minutes or longer to further cure the relief image formed upon development. After development and any post-development cure, the substrate surface bared by development may then be selectively processed, for example chemically etching or plating substrate areas bared of photoresist in accordance with procedures known in the art. Suitable etchants include a hydrofluoric acid etching solution and a plasma gas etch such as an oxygen plasma etch.

The invention also provide methods for forming relief images of the photoresists of the invention, including methods for forming highly resolved patterned photoresist images (for example, a patterned line having essentially vertical sidewalls) of sub-quarter μm dimensions or less, such as sub-0.2 or sub-0.1 μm dimensions.

The invention further provides articles of manufacture comprising substrates such as a microelectronic wafer or a flat panel display substrate having coated thereon the photoresists and relief images of the invention.

### EXAMPLE 1

A positive-acting, chemically amplified photoresist composition was prepared by combining the following polymer (resin), where the monomer amounts indicated are mole

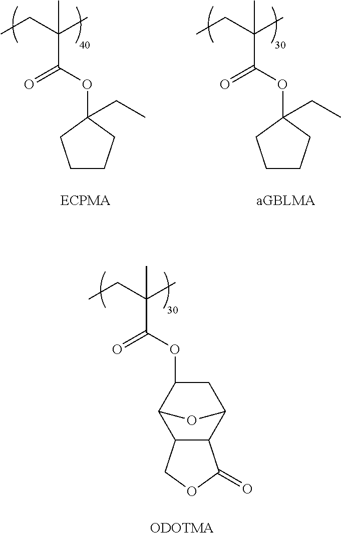

percentages, with a mixture of the following photoacid generators (“PAGs”): triphenylsulfonium hexahydro-4,7-epoxyisobenzofuran-1(3H)-one, 6-(2,2′-difluoro-2-sulfonatoacetic acid ester (TPS-ODOT-DFMS) (6.523% of total solids); and t-butylphenyl tetramethylenesulfonium 4-adamantanecarboxyl-1,1,2,2-tetrafluorobutane sulfonate (TBPTMS-Ad-TFBS) (10.085% of total solids). An amount of a multi-amide quencher from the following Table 1 was also added to the composition. The amount of quencher added was sufficient to maintain a molar ratio of PAGs:multi-amide compound=3.42. The photoresist composition also contained a fluorinated methacrylate surface leveling agent in an amount of 3% by weight based on the total amount of solids. The photoresist composition was formulated in a solvent blend of propylene glycol methyl ether acetate/methyl-2-hydroxy-iso-butyrate/cyclohexanone (20/65/15 wt %). The total solids content of the photoresist formulation was 3-4%.

In Table 1, “n” refers to the number of atoms between the amide carbonyl groups.

TABLE 1

| | | | PAGs:Quencher |
|---|---|---|---|
| Sample | Multi-amide Compound Quencher | n | (mole ratio) |
| 1-1 | N,N,N′,N′-tetrabutyladipamide | 4 | 1:0.55 |
| 1-2 | cis-N,N,N′,N′-tetrabutylcyclohexane- | 4 | 1:0.84 |
| | 1,4-dicarboxamide | | |
| 1-3 | trans-N,N,N′,N′-tetrabutylcyclohexane- | 4 | 1:0.52 |
| | 1,4-dicarboxamide | | |
| 1-4 | N,N′-dibutyl-N,N′- | 8 | 1:0.48 |
| | dimethyldecanediamide | | |

### EXAMPLE 2

Comparative photoresist formulations (“Comparative”) were prepared by repeating Example 1, except that the multi-amide compound quencher of the invention was replaced with a quencher shown in Table 2. The comparative quenchers were used in equimolar amounts as compared to the moles of PAGs. In Table 2, “n” refers to the number of atoms between amide carbonyl groups.

TABLE 2

| Sample | Quencher | n |
|---|---|---|
| Comparative-1 | N,N-diethyldodecanamide | — |
| Comparative-2 | N,N-bis(2-hydroxyethyl)dodecanamide | — |
| Comparative-3 | Tert-butyl (1,3-dihydroxy-2-(hydroxymethyl)propan-2-yl)carbamate | — |
| Comparative-4 | N,N,N′,N′-tetrabutylmalonamide | 1 |
| Comparative-5 | N,N,N′,N′-tetrabutylsuccinamide | 2 |

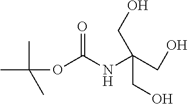

tert-butyl (1,3-dihydroxy-2-(hydroxymethyl)propan-2-yl)carbamate

### EXAMPLE 3

300 mm silicon wafers were spin-coated with AR™26N antireflectant (Rohm and Haas Electronic Materials) to form a first bottom antireflective coating (BARC) on a TEL CLEAN TRACK™ LITHIUS™ i+coater/developer. The wafers were baked for 60 seconds at 205° C., yielding a first BARC film thickness of 77 nm A second BARC layer was next coated over the first BARC using AR™ 124 antireflectant (Rohm and Haas Electronic Materials), and was baked at 205° C. for 60 seconds to generate a 23 nm top BARC layer. Photoresist formulations of either Example 1 or 2 were then coated on the dual BARC-coated wafers and soft-baked at 110° C. for 60 seconds on a TEL CLEAN TRACK™ LITHIUS™ i+coater/developer to provide a resist layer thickness of 110 nm Next, a 30 nm immersion top antireflective layer was spin coated over the photoresist layer using OC2000 (Rohm and Haas Electronic Materials).

The photoresist-coated wafers were exposed through a mask having 45 nm lines and 90 nm pitch on an ASML TWINSCAN™ XT:1900i immersion scanner using a dipole illumination with 1.30 NA, 0.97 outer sigma, 0.77 inner sigma and X polarization. The exposed wafers were post-exposure baked at 95° C. for 60 seconds and then developed using 0.26 N tetramethammonium hydroxide.

The lithographic results are reported in Table 3.

TABLE 3

| | Es | | | |
|---|---|---|---|---|
| Sample | (mJ/cm²) | % EL | MEEF | PCM (nm) |
| 1-1 | 19.5 | 26.2 | 1.00 | <31 |
| 1-2 | 21.2 | 25.7 | 1.02 | <31 |
| 1-3 | 18.7 | 25.5 | 0.87 | <33 |
| 1-4 | 20.5 | 23.8 | 1.12 | <29 |
| Comparative-1 | 18.2 | 9.2 | 3.27 | 41 |
| Comparative-2 | 22.0 | 15.3 | 1.75 | 39 |
| Comparative-3 | 23.9 | 21.0 | 1.22 | 34 |
| Comparative-4 | 25.4 | 24.3 | 1.14 | 33 |
| Comparative-5 | 24.4 | 26.0 | 1.09 | 32 |

Es (Energy to size) is the exposure dose in mJ/cm² of 193 nm wavelength radiation required to image a specified feature (45 nm line/space pattern with 90 nm pitch) while at best focus (+0.01 μm).

EL (Exposure Latitude) is the sensitivity of line width to the exposure dose. A larger % EL is desired.

MEEF (Mask Error Enhancement Factor) is the change in a feature's line width as printed on the wafer compared to the change in line width on the mask (normalized by magnification). For instance, a MEEF of 2.0 would give a 2 nm change on the wafer for every 1 nm change on the mask (normalized by magnification). A MEEF value of 1 or lower is preferred. For the examples given, MEEF is calculated as follows.

Exposure arrays are imaged where the Es is near the center of the array. The dose increment is ˜3% of Es. Exposure latitude plots are generated for 43 nm, 44 nm, 45 nm, 46 nm and 47 nm lines all with 90 nm pitch. Second order polynomial fits are then made for each of the five plots over a range of 0.8×CD to 1.2×CD, where CD is the target line width. The sizing dose, Es, is calculated for the 45 nm line feature. At this Es value, the line width is calculated for the 43 nm, 44 nm, 46 nm and 47 nm lines using the second order polynomial fit. The calculated line width values are then plotted against the mask line widths of 43 nm, 44 nm, 45 nm, 46 nm and 47 nm A linear fit is then made to the 5 points, the slope of which is the MEEF.

PCM (Pattern Collapse Margin), for line/space patterns, is the smallest line measurement at over-exposure (Dose>Es) that has not collapsed. For L/S patterns, a lower PCM is better. For trench patterns, a higher PCM is better. The PCM values of the Comparative samples in Table 3 are the smallest line that did not collapse. Smaller lines printed using the comparative photoresists were found to collapse. In contrast, the PCM values for the Samples of the invention 1-1 to 1-4 were the smallest lines printed. None of the lines printed with the photoresists of the invention collapsed. Accordingly, the PCM values for the Samples of the invention are below (that is “<”) the smallest line that was printed.

As can be seen from the above data, the multi-amide compound quenchers of the invention provide improved lithographic performance (Es, % EL, MEEF and PCM) as compared to conventional mono-amide compound quenchers and multi-amide quenchers that are not part of the invention.

What is claimed is:

1. A photoresist composition comprising:
(a) one or more resins;
(b) one or more photoacid generator compounds; and
(c) one or more multi-amide compounds of the formula: 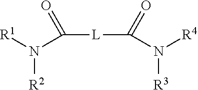
wherein R¹, R², R³, and R⁴ are independently chosen from H, (C₁-C₃₀)alkyl, and amido-substituted(C₁-C₂₀)alkyl; R¹ and R², or R¹ and R³ or R³ and R⁴ may be taken together along with the atoms to which they are attached to form a 5- to 12-membered heterocyclic ring; and L is a linking group providing a spacing of 3 to 8 atoms between the carbonyl groups; wherein the multi-amide compound is free of hydroxyl groups.

2. The photoresist composition of claim 1 wherein the one or more multi-amide compounds are non-polymeric.

3. The photoresist composition of claim 1 wherein the one or more multi-amide compounds are polymeric.

4. The photoresist composition of claim 1 wherein R¹, R², R³, and R⁴ are independently chosen from H, (C₁-C₁₀)alkyl, and amido-substituted(C₁-C₁₀)alkyl.

5. The photoresist composition of claim 1 wherein L is chosen from (C₃-C₁₂)alkylene, ((C₁-C₆)alkylene-O)ₙ(C₁-C₆)alkylene, and 6- to 8-membered heterocyclic rings; wherein n=1-5.

6. The composition of claim 5 wherein L is chosen from (C₃-C₁₂)alkylene.

7. The photoresist composition of claim 1 wherein the (C₁-C₃₀)alkyl and amido-substituted (C₁-C₃₀)alkyl groups of R¹-R⁴, and the (C₃-C₁₂)alkylene, ((C₁-C₆)alkylene-O)ₙ(C₁-C₆)alkylene, and 6- to 8-membered heterocyclic rings of L may be substituted with one or more groups chosen from carboxyl, carboxy(C₁-C₃₀)alkyl, (C₁-C₃₀)alkoxy, sulfonyl, sulfonic acid, sulfonate ester, cyano, halo, and keto.

8. The photoresist composition of claim 1 wherein the one or more multi-amide compounds are selected from: N,N,N′,N′-tetrabutyladipamide; N,N′-dibutyl-N,N′-dimethyldecanediamide; cis-N,N,N′,N′-tetrabutylcyclohexane-1,4-dicarboxamide; and trans-N,N,N′,N′-tetrabutylcyclohexane-1,4-dicarboxamide.

9. A method for forming a photoresist relief image comprising:
(a) applying a coating layer of a photoresist composition of claim 1 on a substrate;
(b) exposing the photoresist coating layer to patterned activating radiation and developing the exposed photoresist layer to provide a relief image.

10. The method of claim 9 wherein the photoresist coating layer is immersion exposed.
